(19) United States
(12) Patent Application Publication
(10) Pub. No.: US 2021/0210406 A1
(43) Pub. Date: Jul. 8, 2021

(54) METHOD FOR PRODUCING A CIRCUIT CARRIER, CIRCUIT CARRIER, METHOD FOR PRODUCING A SEMICONDUCTOR MODULE AND SEMICONDUCTOR MODULE

(71) Applicant: Heraeusstrasse Deutschland GmbH & Co. KG, Hanau (DE)

(72) Inventor: Ronald EISELE, Surendorf (DE)

(73) Assignee: Heraeus deutschland GmbH & Co. KG, Hanau (DE)

(21) Appl. No.: 15/999,684

(22) PCT Filed: Feb. 8, 2017
(86) PCT No.: PCT/EP2017/052742

§ 371 Date: Aug. 20, 2018

(30) Foreign Application Priority Data
Feb. 19, 2016 (EP) 16156491.9

(51) Int. Cl. H01L 23/373; H01L 21/48; H01L 23/00; H01L 23/495

(52) U.S. Cl. CPC H01L 23/3735; H01L 2224/32245; H01L 21/4821; H01L 24/83; H01L 23/49513; H01L 23/49534; H01L 23/49568; H01L 23/49582; H01L 2224/8384; H01L 2924/20105; H01L 2924/20106; H01L 2924/20107; H01L 2924/1203; H01L 2924/13055; H01L 2924/13091; H01L 2224/29139; H01L 21/4882

(57) ABSTRACT

One aspect relates to a method for producing a circuit carrier for a semiconductor component. At least one first copper layer or one first copper-alloy layer with a first coefficient of expansion and at least one second layer made from a second material of low expandability with a second coefficient of expansion, which is smaller than the first coefficient of expansion, are bonded to one another by means of a low-temperature sintering method at a bonding temperature of 150° C. to 300° C.

The invention relates to a method for producing a circuit carrier, particularly a lead frame or a conducting path, for a semiconductor component. Furthermore, the invention relates to a circuit carrier, particularly a lead frame or a conducting path, for a semiconductor component. In addition, the invention relates to a method for producing a semiconductor module, comprising a circuit carrier and at least one semiconductor component, which is bonded to the circuit carrier. Furthermore, the invention relates to a semiconductor module, comprising a circuit carrier and at least one semiconductor component, which is bonded to the circuit carrier.

Power electronics power semiconductors for the most part consist of materials of low expandability and must be mounted on a circuit carrier for electrical contacting and in order to be able to achieve sufficient heat dissipation, which circuit carrier both conducts electrical current satisfactorily and has good thermal conductivity characteristics. In the simplest case, the circuit carrier is a conducting path, particularly a copper conducting path, which is used as a carrier of individual or a plurality of power semiconductors. Power semiconductors typically have silicon (Si) or silicon carbide (SiC). Silicon has a thermal expansion of 2.6 ppm/K, whereas silicon carbide has a thermal expansion of 3.7 ppm/K. These coefficients of expansion are considerably smaller than the coefficients of expansion of typical materials of circuit carriers. Circuit carriers, which are present in the form of a lead frame or a conducting path, usually consist of copper (Cu). Copper has a coefficient of expansion of 17.8 ppm/K.

In order to achieve reliable electrical and thermal contacting, the power semiconductors are soldered onto the circuit carrier with the aid of tin (Sn) or lead (Pb) as base solder. Sintering semiconductor components onto a circuit carrier is also known. In all cases, the power semiconductor and the circuit carrier have a considerable thermal-mechanical maladjustment however, which leads to large stresses directly after cooling from the bonding temperature to room temperature. Depending on the size and thickness of the semiconductor, the maladjustment may become so large that the mechanical stress leads to the destruction of the bond between the semiconductor and the circuit carrier.

Alloys of copper with metals of low expandability are already used to reduce the thermal expansion of copper conducting paths or copper lead frames. Copper-tungsten alloys (CuW) and copper-molybdenum alloys (CuMo) exist for example. These result in thermal expansions of between 8 ppm/K and 12 ppm/K.

CuW and CuMo alloys are technologically complicated to produce and exceptionally expensive. In particular, owing to the high melting-point difference between copper and the alloy constituents tungsten (W) and molybdenum (Mo), alloy formation requires exceptionally comprehensive method steps until alloying is successful. In addition, the thermal conductivity of the pure copper is greatly reduced by alloy formation. This constitutes a considerable disadvantage of cost-intensive alloying.

Starting from this prior art, it is the object of the present invention to specify a method for producing a circuit carrier, particularly a lead frame or a conducting path, for a semiconductor component, which is exceptionally simple and inexpensive to carry out and with the aid of which an optimized circuit carrier can be produced.

Furthermore, it is the object of the present invention to specify a circuit carrier which has exceptionally low expandability and is inexpensive at the same time.

Furthermore, it is an object of the present invention to specify a method for producing a semiconductor module. Furthermore, it is the object of the present invention to specify a developed semiconductor module, wherein the semiconductor module is constructed to have exceptionally low expandability.

According to the invention, this object is achieved, with a view to the method for producing a circuit carrier, particularly a lead frame or a conducting path, for a semiconductor component, by means of the subject matter of claim 1, with a view to the circuit carrier, particularly the lead frame or the conducting path, for a semiconductor component, by means of the subject matter of claim 6, with a view to the method for producing a semiconductor module comprising a circuit carrier and at least one semiconductor component, which is bonded to the circuit carrier, by means of the subject matter of claim 12, and with a view to the semiconductor module comprising a circuit carrier and at least one semiconductor component, which is bonded to the circuit carrier, by means of the subject matter of claim 15.

The invention is based on the idea of specifying a method for producing a circuit carrier, particularly a lead frame or a conducting path, for a semiconductor component, wherein at least one first copper layer or one first copper-alloy layer with a first coefficient of expansion and at least one second layer made from a second material of low expandability with a second coefficient of expansion, which is smaller than the first coefficient of expansion, are bonded to one another at a bonding temperature of 150° C. to 300° C. The bonding of the first copper layer or the first copper-alloy layer to the second layer made from a second material particularly preferably takes place by means of a low-temperature sintering method. The circuit carrier to be produced for at least one semiconductor component can be constructed as a lead frame or as a conducting path.

At least one bonding layer made from a bonding material can be constructed between the copper layer or copper-alloy layer and the second layer. The bonding material can produce a bond which withstands temperatures above the bonding temperature and preferably has a diffusion metal, particularly silver (Ag) and/or a silver alloy and/or gold (Au) and/or a gold alloy and/or copper (Cu) and/or a copper alloy.

The bonding temperature may be 200° C.-280° C., particularly 220° C.-270° C., particularly 240° C.-260° C., particularly 250° C. The bonding temperature preferably essentially corresponds to the mounting temperature during the bonding of the circuit carrier produced to at least one semiconductor component.

The second material of low expandability with the second coefficient of expansion at least of the second layer preferably has a nickel alloy, particularly Invar (Fe₆₅Ni₃₅) or Invar 36 (Fe₆₄Ni₃₀) or Kovar (Fe₅₄Ni₂₉Co₁₇), and/or tungsten (W) and/or an iron-nickel-cobalt alloy (FeNiCo alloy). Molybdenum (Mo) or a molybdenum alloy has proven itself as a particularly preferred material with regards to the second material of the second layer.

In principle, all metals which have a smaller coefficient of expansion than copper or the copper alloy can be used as second materials. The lower the coefficient of expansion of the second material is and at the same time the higher the thermal conductivity of the second material is, the more suited this material is as second material. The electrical conductivity is physically connected to the thermal conductivity. Therefore, all metals which have a good thermal and/or electrical conductivity and a low thermal expansion are well-suited to being used as second material or being included by the second material.

In Column 6, the following table shows the coefficient of expansion of the material listed in Column 1. All materials which correspondingly have a smaller coefficient of expansion than copper are consequently suited to serving as second material or being used as second material.

| | |
|---|---|
| 1) | Material (or symbol) |
| 2) | Density |
| 3) | Modulus of elasticity |
| 4) | Melting temperature |
| 5) | Thermal conductivity |
| 6) | Linear coefficient of expansion (10 + 6*alpha) |
| 7) | Spec. heat |
| 8) | Electrical conductivity |
| 9) | Temperature coefficient of the electrical resistance (10 + 3*alpha) |

| | | | | | | | 8)□El. | |
|---|---|---|---|---|---|---|---|---|
| | | | 4) Temp. | 5)□Th. C. | 6)□Coeff. | | Cond. | 9)□Temp. |
| | 2)□Density | 3)□M. E. | Deg. | cal/□cm | of exp. | 7)□Sp. ht. | m/□ohm | coeff. |
| 1)□Material | kg/□dm³ | kp/mm² | □Celsius | secdeg | m/□mdeg | cal/□gdeg | mm² | 1/□deg |
| Silver | 10.49 | 8160 | 960 | 1.00 | 19.7 | 0.056 | 63 | 4.10 |
| Copper | 8.96 | 12500 | 1083 | 0.94 | 16.2 | 0.092 | 60 | 4.31 |
| Iron | 7.87 | 21550 | 1530 | 0.18 | 11.7 | 0.11 | 10.3 | 6.57 |
| Grey cast | 7.20 | 8000-13000 | 1150-1300 | 0.13 | 9.0 | 0.13 | 1-2 | |
| iron | | | | | | | | |
| Molybdenum | 10.2 | 33630 | 2625 | 0.35 | 5 | 0.061 | 19.4 | 4.73 |
| Monel | 8.58 | 15900 | 1320-1350 | 0.06 | 14 | 0.12 | 1.6 | 0.19 |
| metal | | | | | | | | |
| Nickel | 8.90 | 19700 | 1455 | 0.22 | 13.3 | 0.105 | 14.6 | 6.75 |
| Niobium | 8.57 | 16000 | 2415 | | 7.0 | 0.0065 | 7.7 | |
| Osmium | 22.5 | 57000 | 2700 | | 4.6 | 0.031 | 10.4 | 4.45 |
| Platinum | 21.45 | 17320 | 1774 | 0.17 | 8.9 | 0.032 | 10.2 | 3.92 |
| C15 steel | 7.85 | 20800 | 1510 | 0.12 | 11.1 | 0.11 | 9.3 | 5.7 |
| C35 steel | 7.84 | 20600 | 1490 | 0.12 | 11.1 | 0.11 | 8.6 | 5.2 |
| C60 steel | 7.83 | 20400 | 1470 | 0.11 | 11.1 | 0.11 | 7.9 | 4.7 |
| 41Cr4 | 7.84 | 20700 | 1490 | 0.1 | 11.0 | 0.11 | 8.0 | |
| X10Cr13 | 7.75 | 22000 | 1500 | 0.065 | 10.0 | 0.11 | 1.7 | |
| 36% Ni | 8.13 | 14500 | 1450 | 0.025 | 0.9 | 0.123 | | |
| steel | | | | | | | | |
| Tantalum | 16.6 | 18820 | 3000 | 0.13 | 6.6 | 0.036 | 8.1 | 3.47 |
| Titanium | 4.54 | 10520 | 1800 | 0.041 | 10.8 | 0.126 | 1.25 | 5.46 |
| Vanadium | 6.0 | 15000 | 1735 | | 8.5 | 0.12 | 3.84 | |
| Bismuth | 9.8 | 3480 | 271 | 0.020 | 12.4 | 0.034 | 0.94 | 4.45 |
| Tungsten | 19.3 | 41530 | 3380 | 0.48 | 4.5 | 0.032 | 18.2 | 4.82 |
| Zirconium | 6.5 | 6970 | 1850 | | 10 | 0.066 | 2.44 | 4.4 |

The bonding at least of the first copper layer or at least the first copper-alloy layer at least to the second layer and optionally the bonding layer can take place by means of the application of pressure, particularly using a pressure of 5 MPa-30 MPa, particularly of 10 MPa-28 MPa, particularly of 25 MPa.

A low-temperature sintering which is preferably to be carried out for bonding at least the first copper layer or at least the first copper-alloy layer and at least the second layer and optionally the bonding layer preferably takes place at temperatures of 150° C.-300° C. and at an applied pressure of 5 MPa-30 MPa. Particularly preferably, the low-temperature sintering is carried out at a temperature of 250° C. and a pressure of 25 MPa, wherein the sintering is preferably carried out from 1 to 10 min., for example 4 min.

The bonding temperature in the method for producing a circuit carrier essentially corresponds to the mounting temperature in the bonding of the circuit carrier produced to at least one semiconductor component. The bonding temperature may correspond exactly to the mounting temperature. Furthermore, it is possible that the bonding temperature deviates by at most 20%, in particular at most 15%, in particular at most 10%, in particular at most 5%, from the mounting temperature. The percentual calculation of the deviation of the bonding temperature from the mounting temperature takes place on the basis of a calculation of the difference between the bonding temperature in Kelvin and the mounting temperature in Kelvin.

In addition to carrying out a low-temperature sintering method, it is in addition possible to bond the individual layers of the circuit carrier to one another by means of diffusion soldering with the formation of high-melting intermetallic phases. The use of adhesives for bonding the individual layers of the circuit carrier is also possible.

Preferably, the bonding material is introduced as a sinter material or constituent of the sinter material between at least the first copper layer or at least the first copper-alloy layer and at least the second layer. A composition which can be sintered to form a conductive layer can consequently be used for producing a sintered bond between the layers to be bonded. The composition, which can still be sintered, may have the use type of an ink, a paste or a sinter preform in the form of a layered pressed item. Sinter preforms are created by means of the application and drying of metal pastes or metal sinter pastes. Sinter preforms of this type can still be sintered.

Alternatively, it is possible that the bonding layer is formed as a film, particularly as a metal film, and this film, particularly this metal film, is arranged between the first copper layer or the first copper-alloy layer and the second layer.

It is possible that the sinter paste, which comprises the bonding material or consists of the bonding material, is applied onto the first copper layer or first copper-alloy layer and/or the second layer by means of printing, particularly screen or stencil printing. In other words, the sinter paste is applied onto a first copper layer, if this is present, or onto a first copper-alloy layer, if this is present, and/or onto the second layer.

Optionally, the sinter paste or the metal sinter paste can be dried before carrying out the actual sintering method. Without passing through the fluid state, the metal particles of the sinter paste are bonded during sintering by means of diffusion with the formation of a solid electric-current and heat conductive metallic bond or metal bond between at least the first copper layer or at least the first copper-alloy layer and at least the second layer. A sinter paste is particularly preferably used when bonding the layers, which paste comprises silver and/or a silver alloy and/or silver carbonate and/or silver oxide.

In a further embodiment of the invention, it is possible that a layer, for example applied by electroplating or sputtering, is applied onto at least the first copper layer or onto at least the first copper-alloy layer and/or onto at least the second layer, preferably onto the second layer, before the application of a bonding layer, for better bonding of the bonding layer or joining layer. Insofar as the second layer is a molybdenum layer or the second material of the second layer comprises molybdenum, a nickel-silver layer (NiAg layer) can be applied by electroplating onto the side to be bonded of the second layer. The bonding material, silver in particular, can adhere on this nickel-silver layer particularly well.

The invention is furthermore based in a coordinate aspect on the idea of specifying a circuit carrier, particularly a lead frame or a conducting path, for a semiconductor component, wherein the circuit carrier is preferably produced using an aforementioned method according to the invention.

The circuit carrier according to the invention comprises:
at least one first copper layer or a first copper-alloy layer with a first coefficient of expansion, and
at least one second layer made from a second material of low expandability with a second coefficient of expansion which is smaller than the first coefficient of expansion, wherein the second material has a nickel alloy, particularly Invar (Fe₆₅Ni₃₅) or Invar 36 (Fe₆₄Ni₃₀) or Kovar (Fe₅₄Ni₂₉Co₁₇), and/or tungsten (W) and/or an iron-nickel-cobalt alloy (FeNiCo alloy), particularly preferably molybdenum (Mo).

In a particularly preferred embodiment of the invention, the second material comprises molybdenum (Mo) or the second material is molybdenum (Mo). It is also possible that the second material comprises a molybdenum alloy or is a molybdenum alloy.

At least one first bonding layer can be formed between the first copper layer or the first copper-alloy layer and the second layer, which first bonding layer preferably comprises diffusion metal, particularly silver (Ag) and/or a silver alloy and/or gold (Au) and/or a gold alloy and/or copper (Cu) and/or a copper alloy.

At least the first bonding layer can be formed as a boundary layer of the first copper layer or the first copper-alloy layer and/or the second layer.

It is possible that the bonding layer is a self-contained visible layer. If the bonding material is only applied with a relatively low layer thickness during the production of the circuit carrier according to the invention, the bonding layer in the product produced, namely in the circuit carrier produced, can be formed as a boundary layer of the first copper layer or the first copper-alloy layer and/or the second layer. The bonding material can for example be diffused into the first copper layer or the first copper-alloy layer and/or the second layer at least in certain sections.

Particularly preferably, the bonding material of the bonding layer is silver or a silver alloy, so that the silver or the silver alloy is diffused into the first copper layer or the first copper-alloy layer and/or the second layer at least in certain sections during the formation of the bonding layer as boundary layer.

In a further embodiment of the invention, the circuit carrier has at least one second copper layer or a second copper-alloy layer which is preferably bonded, by means of a second bonding layer made up of a/the bonding material, to the second layer made up of the second material of low expandability. Consequently, the circuit carrier can comprise three layers which are bonded to one another with the aid of two bonding layers.

In a further embodiment of the invention, the circuit carrier can have at least one fourth layer which is formed from a/the second material. The fourth layer is preferably bonded to a copper layer or a copper-alloy layer by means of a third bonding layer made from a/the bonding material. In this embodiment of the invention, the circuit carrier comprises four layers, which are either formed from copper or a copper alloy or from a/the second material, wherein these four layers are bonded to one another by means of at least three bonding layers.

In a further embodiment of the invention, the circuit carrier can have at least one third copper layer or a third copper-alloy layer. The third copper layer or third copper-alloy layer can be bonded to a copper layer or copper-alloy layer. This bond can also be produced by means of a bonding layer made from a/the bonding material.

The circuit carrier can have a symmetrical arrangement of the individual layers and bonding layer(s). The symmetrical arrangement of the individual layers and bonding layer(s) is preferably formed in such a manner that a flat circuit carrier is formed. A symmetrical arrangement of the individual layers is to be understood such that in the case of a theoretical formation of an axis of symmetry through the circuit carrier, a symmetrical arrangement of the individual layers and bonding layer(s) with consistent materials and layer thicknesses is formed both above and below the axis of symmetry. The axis of symmetry halves the arrangement of the individual layers with respect to the total thickness of the circuit carrier, wherein the total thickness of the circuit carrier is formed by adding the individual layer thicknesses.

When forming a symmetrical arrangement of the individual layers and bonding layer(s), it is possible to form a flat circuit carrier.

In certain applications, it is required that the surface, on which at least one semiconductor component is deposited, is completely flat. This prevents running of contacting material for example and thus “slippage” of a semiconductor component bonded to the circuit carrier by means of the contacting material.

In an alternative embodiment of the invention, it is possible that the individual layers and bonding layer(s) are arranged asymmetrically. The individual layers and bonding layer(s) are in particular arranged asymmetrically such that a convexly or concavely shaped circuit carrier is formed. A convexly or concavely shaped circuit carrier can also be described as a circuit carrier with curvature or with a curved side. The circuit carrier preferably has a controlled convex or concave shape. In other words, the maximum curvature is defined.

An asymmetrical arrangement can be seen by means of a theoretically formed axis of symmetry. The axis of symmetry halves the total thickness of the arrangement of the individual layers, wherein the total thickness is defined by adding the individual layer thicknesses of the circuit carrier. The curvature or the convex or concave shape of the circuit carrier is preferably controlled by arranging and/or forming the second layer and/or at least the fourth layer made from a/the second material, namely the material of low expandability. The second layer and/or at least the fourth layer is or are pre formed asymmetrically in relation to the total arrangement of all layers and bonding layer(s), so that an axis of symmetry is created in a targeted manner from the expansion of the circuit carrier produced.

Depending on the use case, by means of the position and/or formation of the second layer and/or at least the fourth layer made from a second material of low expandability, a curved circuit carrier can be created after final cooling. To this end, the circuit carrier according to the invention is produced with the aid of the previously mentioned method according to the invention and connected with the subsequently mentioned method according to the invention for producing a semiconductor module with at least one semiconductor component.

In a further embodiment of the invention, the second layer made from a second material of low expandability can be embedded in a copper layer or a copper-alloy layer. In the copper layer or copper-alloy layer, this may for example be the first copper layer or first copper-alloy layer or the second copper layer or second copper-alloy layer.

In a further embodiment of the invention, the second layer is formed in a frame-like and/or grid-like and/or wire-like manner from a second material of low expandability. Preferably, this formation of the second layer and/or a fourth layer takes place in combination with the embedding of the respective layer into a copper layer or a copper-alloy layer. Furthermore, it is possible that the second layer made from a second material of low expandability has a smaller width or length than the copper layer or copper-alloy layer arranged thereabove and/or therebelow.

If the second layer is formed in a grid-like and/or wire-like manner, shear stresses between the second layer made from a material of low expandability and a copper layer or copper-alloy layer located thereabove and/or therebelow can be absorbed in a better manner. Bonding material, particularly solder or sinter material or conductive adhesive, may be located in the intermediate spaces of the wires or the grid. In addition, it is possible that copper or a copper alloy is located in the intermediate spaces of the wires or the grid. In this embodiment, a copper layer or copper-alloy layer formed below the second layer can for example be pressed into the intermediate spaces of the wires or the grid during the bonding of the layers.

During operation, the circuit carrier according to the invention contributes according to the invention to a maximum heat dissipation of a semiconductor component bonded to the circuit carrier. The performance and the service life of the semiconductor component is maximized on the basis of a circuit carrier according to the invention.

In a coordinate aspect, the invention is furthermore based on the idea of specifying a method for producing a semiconductor module, which comprises a circuit carrier and at least one semiconductor component, which is bonded to the circuit carrier. Preferably, the circuit carrier is a previously mentioned circuit carrier according to the invention or a circuit carrier which was produced using a previously mentioned method according to the invention.

The method according to the invention for producing a semiconductor module is based on the fact that the semiconductor component is bonded by means of a contacting layer to the circuit carrier at a mounting temperature of 150° C.-300° C., wherein the mounting temperature substantially corresponds to the bonding temperature during the bonding of the layers of the circuit carrier.

The mounting temperature may correspond exactly to the bonding temperature. Preferably, the mounting temperature deviates by at most 20%, in particular at most 15%, in particular at most 10%, in particular at most 5%, from the bonding temperature. The percentual calculation of the deviation of the mounting temperature from the bonding temperature takes place on the basis of a calculation of the difference between the mounting temperature in Kelvin and the bonding temperature in Kelvin.

The mounting temperature may be 200° C.-280° C., in particular 220° C.-270° C., in particular 240° C.-260° C., in particular 250° C.

The semiconductor component is preferably applied onto the surface of the circuit carrier or bonded to the surface of the circuit carrier, wherein the surface is preferably formed by a copper layer or a copper-alloy layer. The surface can also be termed the uppermost side of the circuit carrier.

The contacting layer may for example be a sinter paste. It is also possible that the contacting layer is an adhesive layer or a solder layer.

In an embodiment of the invention, the bonding of the layers of the circuit carrier and the bonding of the semiconductor component to the circuit carrier can take place simultaneously. In this embodiment, all layers, bonding layer(s) and the semiconductor component to be bonded are arranged above one another and for example bonded to one another by means of a low-temperature sintering method at the same time.

By means of the combination of the method according to the invention for producing a circuit carrier with the method according to the invention for producing a semiconductor module, it is possible to produce a circuit carrier with asymmetric arrangement of the layers and bonding layer(s) such that a defined convex or concave deformation of the circuit carrier, in other words a defined maximum curvature, is generated. The individual layers and bonding layer(s) are arranged asymmetrically to one another. The asymmetry can be controlled by means of the number of layers and/or by means of the layer thicknesses.

The asymmetric arrangement of layers and bonding layer(s) is interconnected at a bonding temperature which substantially corresponds to the mounting temperature of the semiconductor component with the circuit carrier.

The bonding of the semiconductor component to the circuit carrier follows. Here, it can be seen that the concave or convex deformation degrades during the reheating of the asymmetric circuit carrier produced and, following the bonding of the semiconductor component to the substrate plate, assumes a temperature-stable final shape in a new stress equilibrium in a manner which meets the requirements.

The temperature-stable final shape may be a defined maximum curvature. For example, a defined maximum curvature is 100 μm. In addition, the temperature-stable final shape may be a completely flat semiconductor module.

The invention is furthermore based on the idea of specifying a semiconductor module, wherein the semiconductor module is preferably produced using a previously mentioned method according to the invention. The semiconductor module comprises a circuit carrier and at least one semiconductor component which is bonded to the circuit carrier. The circuit carrier is preferably a circuit carrier according to the invention or a circuit carrier which is produced by means of a previously mentioned method according to the invention.

The semiconductor component may be a diode or an IGBT (bipolar transistor with insulated gate electrode) or a MOSFET transistor. Preferably, the semiconductor component is a power semiconductor.

According to a preferred embodiment of the semiconductor module according to the invention, the second layer of the circuit carrier is embedded in a copper layer or a copper-alloy layer, wherein the semiconductor component is constructed above the second layer. In the case of a design of this type of the second layer in the semiconductor module, the area of the second layer is substantially smaller than the area of the at least one copper layer or the at least one copper-alloy layer. Preferably, the area of the second layer is not smaller than 80% of the area of the semiconductor component. In this case, “above” is a position of the semiconductor component in vertical extension to the second layer. A further layer may also be located between the second layer and the semiconductor component.

Preferably, the second layer has the same side ratio as the semiconductor component arranged thereabove. The achieved reduction of the area of the second layer compared to the area of the copper layer or copper-alloy layer reduces the expansion maladjustment in a concentrated and local manner in the region of the low-expanding semiconductor component. In the circuit carrier, a section is formed which does not have a second layer or in other words is free from the second layer. In this section, there is only copper or a copper alloy. In such an embodiment of the semiconductor module there is a particularly high z thermal conductivity. z thermal conductivity is understood to mean the thermal conductivity starting from the semiconductor component in the direction of the layers of the circuit carrier located therebelow.

The semiconductor component may be constructed concurrently to the second layer.

In a further embodiment of the invention, the second layer can be embedded in a copper layer or a copper-alloy layer, wherein the second layer is constructed in a frame-like manner and frames a copper-layer section or a copper-alloy-layer section, wherein the semiconductor component is constructed above the copper-layer section or copper-alloy-layer section. In this case, “above” is a position of the semiconductor component in vertical extension to the second layer. A further layer may also be located between the second layer and the semiconductor component.

It is possible that the edge lengths of the copper-layer section or copper-alloy-layer section is at most 150% of the edge lengths of the semiconductor component. The width of the second layer of frame-like construction is preferably 10%-100% of the shortest edge length of the semiconductor component. The frame-like construction of the second layer from material of low expandability effects an expansion reduction within the semiconductor module. By contrast, the surrounded copper-alloy-layer section or copper-layer section effects a maximum z thermal conductivity on the basis of the copper material or copper-alloy material.

In a further embodiment of the invention, the area size of the second layer, which is preferably formed between at least two copper layers and/or copper-alloy layers, is limited to a shape adapted for the distribution of the mechanical shear stress between the semiconductor component and the circuit carrier. Often, the shear stress between the semiconductor component and the circuit carrier is particularly large along the diagonal of the semiconductor component. The shear stresses may also extend beyond the diagonal. The shear stress distribution is substantially point-symmetrical to the geometric centre of the semiconductor component.

A minimized area of the second layer made from material of low expandability is consequently an area which extends proportionately further in the diagonals of the semiconductor component than in the region of the coordinate axes of the semiconductor component. In other words, the second layer has a surface form such that the extent in the region of the diagonals of the semiconductor component is larger than in the region of the coordinate axes of the semiconductor component. The surface form of the second layer formed is similar to a four leaf clover. A copper-layer section or a copper-alloy-layer section, which is embedded into the second layer, can be constructed in the centre of the area of the second layer. Such a design of a semiconductor module improves the thermal conductivity by means of dispensing with material of low expandability and owing to the use of copper or a copper alloy.

The invention is explained in more detail in the following with further details and with reference to the attached schematic drawings on the basis of exemplary embodiments. In the figures:

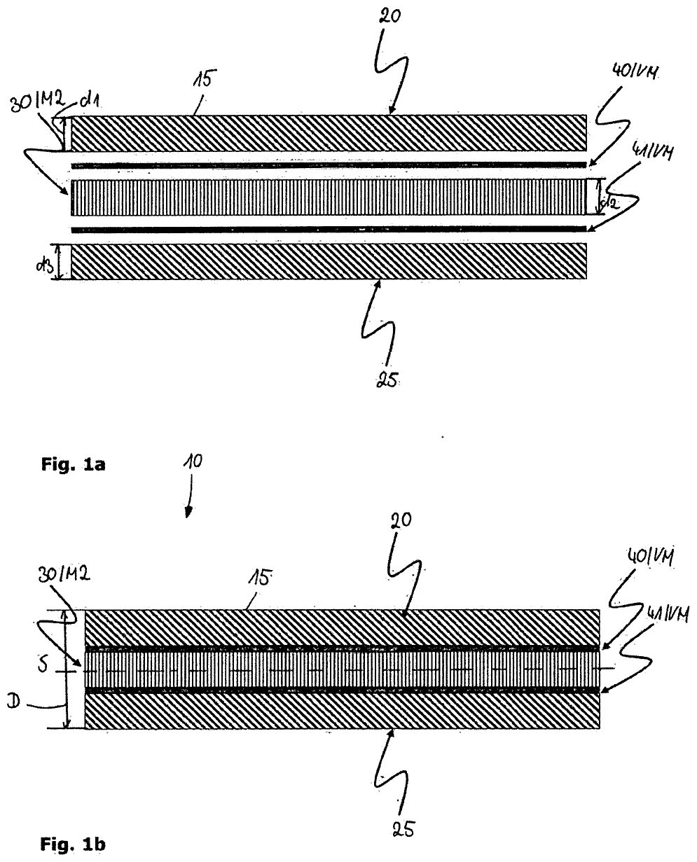

FIG. 1a shows the arrangement of individual layers of a circuit carrier;

FIG. 1b shows a circuit carrier according to FIG. 1a in the bonded state;

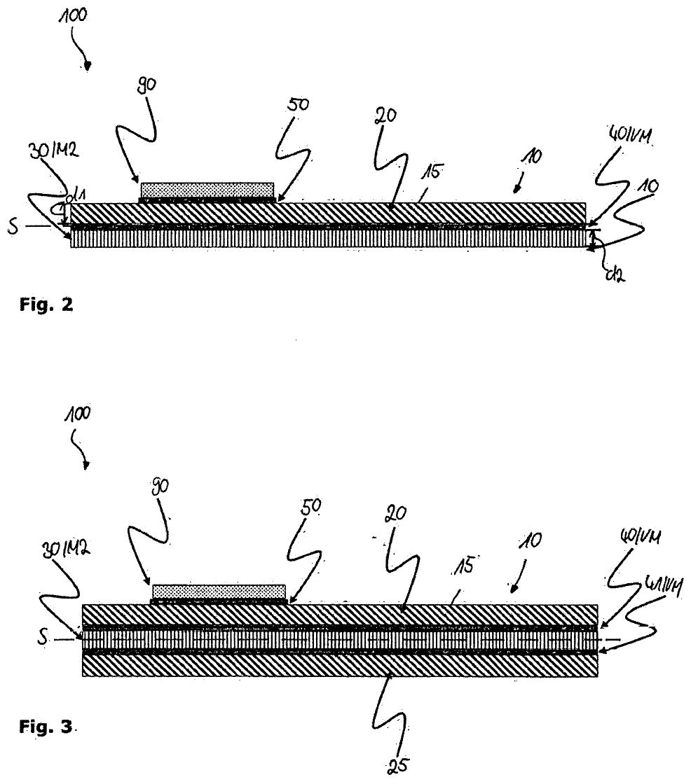

FIG. 2 shows a semiconductor module according to a first exemplary embodiment;

FIG. 3 shows a semiconductor module according to a second exemplary embodiment;

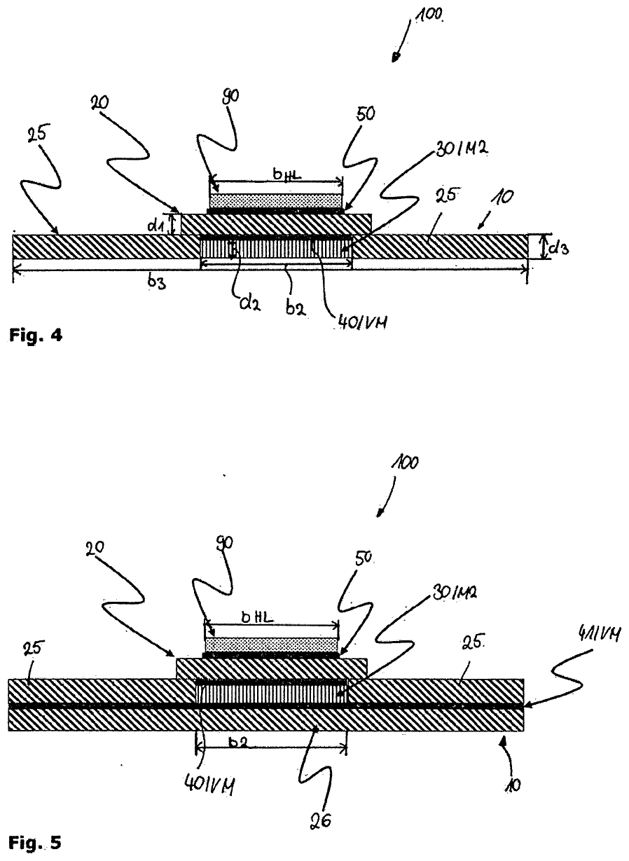

FIG. 4 shows a semiconductor module according to a third exemplary embodiment;

FIG. 5 shows a semiconductor module according to a fourth exemplary embodiment;

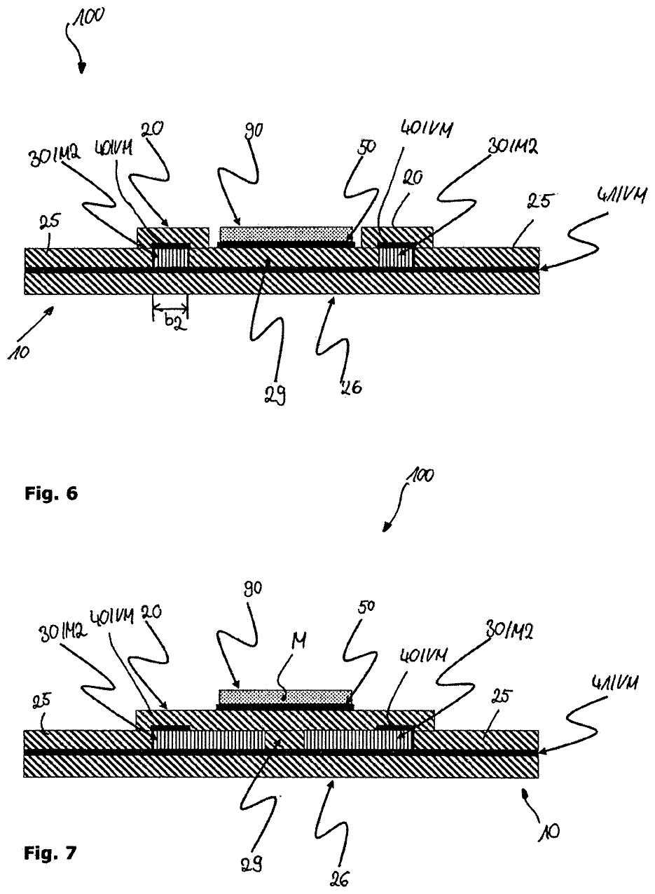

FIG. 6 shows a semiconductor module according to a fifth exemplary embodiment; and

FIG. 7 shows a semiconductor module according to a sixth exemplary embodiment.

In the following, the same reference numerals are used for the same parts and parts with the same action.

The individual layers of a circuit carrier 10 (see FIG. 1b) to be produced are illustrated in FIG. 1a. Consequently, the circuit carrier 10 to be produced comprises a first layer 20 made from copper, a second layer 30 made from a second material M2 and a second copper layer 25.

The material M2 is a material of low expandability with a second coefficient of expansion, which is lower than the coefficient of expansion of copper. The second material M2 may be a nickel alloy, particularly Invar (Fe₆₅Ni₃₅) or Invar 36 (Fe₆₄Ni₃₆) or Kovar (Fe₅₄Ni₂₉Co₁₇), and/or tungsten (W) and/or an iron-nickel-cobalt alloy (FeNi Co alloy).

In the present exemplary embodiment the material M2 is molybdenum.

A first bonding layer 40 made from a bonding material VM is formed between the first copper layer 20 and the second layer 30. A second bonding layer 41 made from the bonding material VM is formed between the second layer 30 and the second copper layer 25. The bonding material VM of the bonding layers 40 and 41 creates a bond between the layers 20, 25 and 30, which withstands temperatures above a bonding temperature. The bonding layer preferably has diffusion material, particularly silver and/or a silver alloy and/or gold and/or a gold alloy and/or copper and/or a copper alloy.

The bonding layer is preferably formed as a sinter layer, particularly as a sinter paste. This sinter paste, which preferably has one of the listed diffusion metals, can for example be applied by means of a printing method.

Preferably, the layers 20, 25, 30, 40 and 41 are bonded to one another by means of a low-temperature sintering method at a bonding temperature of 150° C.-300° C. The bonding temperature is particularly preferably 250° C. The bonding temperature for bonding the layers 20, 25 and 30 with the aid of the bonding layers 40 and 41 substantially corresponds to the mounting temperature during the bonding of the circuit carrier 10 produced to a semiconductor component which is to be applied.

The bonding of the first copper layer 20 to the second layer 30 and to the second copper layer 25 preferably takes place by means of pressure loading, particularly with a pressure of 5 MPa-30 MPa, particularly of 25 MPa.

The circuit carrier 10 produced can be seen in FIG. 1b. The bonding layers 40 and 41 can be seen in the same. It is possible that the bonding layers 40 and 41 are formed as boundary layers of the first copper layer 20, the second copper layer 25 and the second layer 30.

As can be seen in FIGS. 1a and 1b, the layer thicknesses d1 of the first copper layer 20, d2 of the second layer 30 and d3 of the second copper layer 25 are the same. With the aid of the axis of symmetry S drawn in FIG. 1b it becomes clear that the structure of the circuit carrier 10 is a symmetrical structure of the individual layers 20, 25 and 30 and the bonding layers 40 and 41. The axis of symmetry S halves the total thickness D of the circuit carrier 10. The total thickness D is formed by means of the addition of the layer thicknesses d1, d2 and d3 and the layer thicknesses of the bonding layers 40, 41. A symmetrical structure of the circuit carrier 10 is shown above and below the axis of symmetry S.

In a preferred embodiment, the layer thickness d1 of the first copper layer 20 is 0.5 mm-3.0 mm, the layer thickness d2 of the second layer 30 is 0.1 mm-1.0 mm and the layer thickness d3 of the second copper layer 25 is 0.5 mm-3.0 mm. The thicknesses of the first bonding layer and second bonding layer are preferably 1 μm-50 μm.

A semiconductor module 100 is illustrated in FIG. 2. The semiconductor module 100 comprises a semiconductor component 90 and a circuit carrier 10. The semiconductor component 90 may for example be a diode or an IGBT or a MOSFET transistor. The semiconductor component 90 is bonded to the circuit carrier 10 by means of a contacting layer 50. The contacting layer 50 may for example be a solder layer or an electrically conductive adhesive layer or a sinter layer.

The illustrated circuit carrier 10 consists of a first copper layer 20 and a second layer 30 made from a second material M2. The second material M2 is molybdenum. The first layer 20 is bonded to the second layer 30 by means of a bonding layer 40, which consists of bonding material VM.

The semiconductor component 90 is applied onto the side 15 of the circuit carrier 10 facing the semiconductor component 90 with the aid of the contacting layer 50. The surface 15 of the circuit carrier 10 to be bonded to the semiconductor component 90 is the first side 15 of the first copper layer 20, wherein the first side 15 of the copper layer 20 is formed facing away from the second layer 30.

The indicated axis of symmetry S shows that in the embodiment according to FIG. 2, an asymmetric arrangement of the layers 20, 30 and 40 is present. The layer thickness d1 of the first copper layer 20 is larger than the layer thickness d2 of the second layer 30.

A semiconductor module 100 according to a second exemplary embodiment is illustrated in FIG. 3. The circuit carrier 10 of FIG. 3 is the circuit carrier 10 illustrated in FIG. 1b, that is to say a circuit carrier 10 with symmetrical arrangement. Also, in this embodiment the semiconductor component 90 is applied on the first side 15 of the first copper layer 20 by means of a contacting layer 50.

A further exemplary embodiment with regards to a circuit carrier 10 of a semiconductor module 100 according to the invention is illustrated in FIG. 4. Consequently, the second layer 30 made from a second material M2, particularly from molybdenum, is embedded into the second copper layer 25. Both the width b2 of the second layer 30 and the thickness d2 of the second layer 30 are lower than the width b3 of the second copper layer will 25 and the thickness d3 of the second copper layer 25. The semiconductor component 90 is mounted on the circuit carrier 10 above the second layer 30. The width b2 of the second layer is slightly smaller in this case than the width bHL of the semiconductor component 90.

The circuit carrier 10 comprises a first copper layer 20, which is arranged in certain sections above the second copper layer 25 and above the second layer 30. To bond the first copper layer 20 to the second copper layer 30, a bonding layer 40 made from bonding material VM is formed between the first copper layer 20 and the second layer 30 made from second material. M2.

As the layer thickness d2 of the second layer 30 is lower than the layer thickness d3 of the second copper layer 25, the first bonding layer 40 can be introduced for example by means of a doctor blade into the recess formed owing to the different layer thicknesses d2 and d3. Preferably, the first copper layer 20 is a copper conducting path.

A method according to the invention for producing the circuit carrier 10 or the semiconductor module 100 first provides that the second layer 30 is bonded to the first copper layer 20 for example by means of a low-temperature sintering method. Owing to the asymmetric structure of the circuit carrier 10, a deformation occurs first upon cooling of the circuit carrier 10 to room temperature. If the semiconductor element 90 is then mounted on the circuit carrier 10 in a second work step, particularly by means of sintering, diffusion soldering or adhesive bonding, a mechanical stress equalization occurs which in turn leads to a flat conducting path shape.

This type of stress-equalized bonding can also take place in one process step. To this end, the first copper layer 20, particularly the copper conducting path, is positioned onto the second layer 30, which is embedded into the second copper layer 25, and in turn the semiconductor component 90 is positioned thereon. The bonding layer 40 is located between the first copper layer 20 and the second layer 30 made from a second material. M2 and the contacting layer 50 is located between the semiconductor component 90 and the first copper layer 20. Preferably, both the contacting layer 50 and the first bonding layer 40 are a silver sinter layer, so that all layers and the semiconductor component 90 can be bonded to one another in a single process step.

A similar embodiment of a semiconductor module 100 compared to FIG. 4 is illustrated in FIG. 5. In this case also, the second layer 30 is embedded into the second copper layer 25. The first copper layer 20 is formed between the semiconductor component 90 and the second layer 30. Furthermore, a third copper layer 26 is formed. The second copper layer 25 and the second layer 30 are bonded to the third copper layer 26 by means of a second bonding layer 41 made from bonding material VM.

Overall, the area of the second layer 30 made from material of low expandability, such as e.g. molybdenum, is substantially smaller than the areas of the second copper layer 25 and the third copper layer 26. The reduction in the area of the second layer 30 is not less than 80% of the area of the semiconductor component 90 however. In the example illustrated according to FIG. 5, the area of the second layer 30, as is indicated by the width b2 of the second layer, is larger than the area of the semiconductor component 90. The area of the second layer 30 preferably has the same side ratio as the semiconductor component 90. The reduction in the area of the second layer 30 made from material of low expandability compared to the areas of the second copper layer 25 and the third copper layer 26 reduces the expansion maladjustment in a concentrated and local manner in the region of the low-expanding semiconductor component 90.

The first copper layer 20 covers the second layer 30 completely. In the case of a pressing bonding technology, a contour-following first copper layer 20 can be formed owing to an applied mounting pressure. In this case, a plateau may be formed, which carries the semiconductor component 90.

A further semiconductor component 100 with a further embodiment with regards to a circuit carrier 10 according to the invention is illustrated in FIG. 6. The second layer 30 of the circuit carrier 10 is formed as a rectangular frame in this exemplary embodiment. The second layer 30 made from material of low expandability and formed as a rectangular frame is embedded into the second copper layer 25. The second layer 30 is bonded to the first copper layer 20 by means of a first bonding layer 40 made from bonding material VM. The first copper layer 20 is also formed as a rectangular frame. The second layer 30 frames a copper-layer section 29, wherein the semiconductor component 90 is formed above the copper-layer section 29. At most, the edge lengths of the copper-layer section 29 should be 150% of the edge lengths of the semiconductor component 90. The width b2 of the second layer 30 of frame-like construction is at least 10% and at most 100% of the smallest edge length of the semiconductor component 90.

The circuit carrier 10 furthermore has a third copper layer 26. This third copper layer 26 is bonded to the second layer 30 and the second copper layer 25 by means of a second bonding layer 41.

The frame-like design of the second layer 30 effects an expansion reduction, wherein the copper-layer section 29, on which the semiconductor component 90 is applied by means of a contacting layer 50, effects a maximum z thermal conductivity owing to the copper material. The thermal conductivity starting from the semiconductor component 90 in the direction of the third copper layer 26 is defined as z thermal conductivity. A contour-following copper layer can be formed on the basis of a pressing bonding technology, such as e.g. on the basis of a sintering method, owing to the mounting pressure. The second layer 30 covered with the first copper layer 20 in this case forms a flat plateau lowered in the direction of the copper-layer section 29, which plateau carries the semiconductor component 90.

The circuit carrier 10 of the semiconductor module 100 of FIG. 7 likewise has a first copper layer 20, a second copper layer 25 and a third copper layer 26. The second layer 30 is embedded into the second copper layer 25. The first copper layer 20 is of square or rectangular construction and covers the second layer 30. The first copper layer 20 is bonded to the second layer 30 by means of a first bonding layer 40 made from bonding material VM and of frame-like construction. The second copper layer 25 is in turn bonded to the third copper layer 26 using a second bonding layer 41.

The extent or the size of the area of the second layer 30 made from material M2 of low expandability is in this exemplary embodiment limited to a shape adapted to the distribution of the mechanical shear stress between the semiconductor component 90 and the circuit carrier 10. The shear stress is particularly large between the semiconductor component 90 and the circuit carrier 10 along the diagonals (and beyond) of the semiconductor component 90. The shear stress distribution is substantially point-symmetrical to the centre point M of the semiconductor component 90.

A minimum possible design in this case with regards to the area of the second layer 30 therefore results in an area which extends somewhat beyond the diagonals of the semiconductor component 90. The area of the second layer 30 extends further beyond the diagonals than in the region of the coordinate axes of the semiconductor component 90. The resultant surface form (which would be visible in a plan view onto the second layer 30) is similar to a four leaf clover. To improve the thermal conductivity, a copper-layer section 29 can be formed in the second layer 30 in the region of the centre point M of the semiconductor component 90.

1-18. (canceled)

19. A method for producing a circuit carrier for a semiconductor component, comprising:
bonding together at least one first copper layer or one first copper-alloy layer with a first coefficient of expansion and at least one second layer made from a second material of low expandability with a second coefficient of expansion, which is smaller than the first coefficient of expansion;
wherein the layers are bonded to one another by means of a low-temperature sintering method, at a bonding temperature of 150° C.-300° C.

20. The method of claim 19, further comprising forming at least one first bonding layer, made from a bonding material, between the first copper layer or the first copper-alloy layer and the second layer, wherein the bonding material produces a bond that withstands temperatures above the bonding temperature and has a diffusion metal comprising one of a group comprising silver (Ag), a silver alloy, gold (Au), a gold alloy, copper (Cu), and a copper alloy.

21. The method of claim 19, wherein the bonding temperature is between 240° C.-260° C., wherein the bonding temperature essentially corresponds to a mounting temperature during the bonding of the circuit carrier produced to at least one semiconductor component.

22. The method of claim 19, wherein the second material comprises one of a group comprising a nickel alloy, Invar (Fe₆₅Ni₃₅), Invar 36 (Fe₆₄Ni₃₆), Kovar (Fe₅₄Ni₂₉Co₁₇), tungsten (W), an iron-nickel-cobalt alloy (FeNiCo alloy), and molybdenum (Mo).

23. The method of claim 19, wherein the bonding of the copper layer or the copper-alloy layer to the second layer and the bonding layer takes place by means of the application of pressure between 10 MPa-28 MPa.

24. A circuit carrier for a semiconductor component, comprising:
at least one first copper layer or a first copper-alloy layer with a first coefficient of expansion, and
at least one second layer made from a second material of low expandability with a second coefficient of expansion which is smaller than the first coefficient of expansion, the second layer bonded to the at least one first copper layer or one first copper-alloy layer;
wherein the second material comprises one of a group comprising a nickel alloy, Invar (Fe₆₅Ni₃₅), Invar 36 (Fe₆₄Ni₃₆), Kovar (Fe₅₄Ni₂₉Co₁₇), tungsten (W), an iron-nickel-cobalt alloy (FeNiCo alloy), and molybdenum (Mo).

25. The circuit carrier of claim 24, wherein at least one first bonding layer is formed between the first copper layer or the first copper-alloy layer and the second layer, and wherein the at least one first bonding layer comprises a diffusion metal comprising one of a group comprising silver (Ag), a silver alloy, gold (Au), a gold alloy, copper (Cu), and a copper alloy.

26. The circuit carrier of claim 25, wherein at least the first bonding layer is formed as a boundary layer of the first copper layer or the first copper-alloy layer and at least the second layer.

27. The circuit carrier of claim 24, wherein at least one second copper layer or a second copper-alloy layer, which is bonded by means of a second bonding layer comprising a bonding material, to the second layer comprising the second material of low expandability.

28. The circuit carrier of claim 24, wherein the second layer is embedded in a copper layer or a copper-alloy layer.

29. The circuit carrier of claim 24, wherein the second layer is formed in one of a frame-like, grid-like, and wire-like manner.

30. A method for producing a semiconductor module, comprising:
providing a circuit carrier comprising:
bonding together at least one first copper layer or one first copper-alloy layer with a first coefficient of expansion and at least one second layer made from a second material of low expandability with a second coefficient of expansion, which is smaller than the first coefficient of expansion;
wherein the layers are bonded to one another by means of a low-temperature sintering method, at a bonding temperature of 150° C.-300° C.;
providing at least one semiconductor component that is bonded to the circuit carrier;
bonding the semiconductor component by means of a contacting layer to the circuit carrier at a mounting temperature of 150° C.-300° C.;
wherein the mounting temperature substantially corresponds to the bonding temperature during the bonding of the layers of the circuit carrier.

31. The method of claim 30, wherein the bonding of the layers of the circuit carrier and the bonding of the circuit carrier to the semiconductor component take place simultaneously.

32. The method of claim 30, wherein the mounting temperature is between 240° C.-260° C.

33. A semiconductor module, comprising
a circuit carrier, comprising:
at least one first copper layer or a first copper-alloy layer with a first coefficient of expansion, and
at least one second layer made from a second material of low expandability with a second coefficient of expansion which is smaller than the first coefficient of expansion, the second layer bonded to the at least one first copper layer or one first copper-alloy layer;
wherein the second material comprises one of a group comprising a nickel alloy, Invar (Fe₆₅Ni₃₅), Invar 36 (Fe₆₄Ni₃₆), Kovar (Fe₅₄Ni₂₉Co₁₇), tungsten (W), an iron-nickel-cobalt alloy (FeNiCo alloy), and molybdenum (Mo); and
at least one semiconductor component comprising one of a diode, an IGBT, and a MOSFET transistor that is bonded to the circuit carrier.

34. The semiconductor module of claim 33, wherein the second layer is embedded in a copper layer or a copper-alloy layer, and wherein the semiconductor component is constructed above the second layer.

35. The semiconductor module of claim 33, wherein the second layer is embedded in a copper layer or a copper-alloy layer, wherein the second layer is constructed in a frame-like manner and frames a copper-layer section or a copper-alloy-layer section, and wherein the semiconductor component is constructed above the copper-layer section or copper-alloy-layer section.

36. The semiconductor module of claim 35, wherein edge lengths of the copper-layer section or the copper-alloy-layer section are at most 150% of edge lengths of the semiconductor component and the width of the second layer of frame-like construction is 10%-100% of the shortest edge length of the semiconductor component.
